(19) United States
(12) Patent Application Publication
(10) Pub. No.: US 2010/0029091 A1
(43) Pub. Date: Feb. 4, 2010

(54) Method of Forming Tunnel Insulation Layer in Flash Memory Device

(75) Inventors: Woo Ri Jeong, Icheon-si (KR); Seung Woo Shin, Hwaseong-si (KR); Sang Soo Lee, Seoul (KR); Jae Mun Kim, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Gyeonggi-do (KR)

(21) Appl. No.: 12/495,165

(22) Filed: Jun. 30, 2009

(30) Foreign Application Priority Data
Jul. 29, 2008 (KR) 10-2008-0073895

(51) Int. Cl. H01L 21/316

(52) U.S. Cl. 438/762; 257/E21.283

(57) ABSTRACT

A method of forming a tunnel insulating layer in a flash memory device, comprising: forming an oxide layer on a semiconductor substrate, forming a nitrogen-containing layer to a surface of the oxide layer, and forming a nitrogen-accumulating layer on an interface defined between the semiconductor substrate and the oxide layer.

### CROSS-REFERENCE TO RELATED APPLICATION

The priority benefit of Korean Patent Application No. 10-2008-0073895, filed on Jul. 29, 2008, the entire disclosure of which is incorporated herein by reference, is claimed.

### BACKGROUND OF THE INVENTION

The invention relates generally to a method for forming a tunnel insulating layer in a flash memory device and, more particularly, to a method for forming a tunnel insulating layer in a flash memory device, capable of improving leakage current and breakdown voltage characteristics.

A flash memory device is a non-volatile memory device that retains data stored in the memory cell in the absence of supplied power and is capable of performing an electrical erase function at a high rate in a state where the flash memory device is mounted to a circuit board. Due to a structure that favors a high degree of integration, the flash memory device has been the subject of much study. A unit cell of a flash memory device is formed by sequentially laminating a tunnel oxide layer, a floating gate, a dielectric layer, and a control gate on an active area of a semiconductor substrate. Unlike a gate oxide layer in a conventional transistor, the tunnel oxide layer itself acts as a passage through which data are transferred; thus, an excellent thin film characteristic for the tunnel oxide layer is required.

In a NAND flash memory device, since all program operations and erase operations are performed in a Fowler-Nordheim (F-N) tunneling method, if the program operation and the erase operation are repeated many times, the tunnel oxide layer deteriorates so that the flash memory device cannot fully perform its functions. Accordingly, the tunnel oxide layer is as thin as possible to enhance the program speed, while nitrogen is implanted into the thin layer to prevent the thin film characteristic from being degraded. Conventionally, a method for improving the thin film characteristic has been utilized. This method comprises performing an oxidation process to grow a pure oxide layer and subsequently performing an annealing process utilizing N₂O gas or NO gas to distribute nitrogen with a concentration of 2 at % to 3 at % on an interface between a tunnel oxide layer and a semiconductor substrate.

However, it is difficult to satisfactorily secure a breakdown voltage characteristic or a leakage current characteristic by a distribution of nitrogen with a concentration of 2 at % to 3 at % on the tunnel oxide layer the thickness of which has just been reduced. In addition, in a PMOS transistor, a characteristic of a gate insulating layer is subject to degradation by penetration of boron.

### SUMMARY OF THE INVENTION

The invention provides a method of forming a tunnel insulating layer in a flash memory device, comprising performing a nitridation treatment to form a tunnel insulating layer, and forming a nitrogen-accumulating layer.

A method of forming a tunnel insulating layer in a flash memory device according to one embodiment of the invention comprises forming an oxide layer on a semiconductor substrate, forming a nitrogen-containing layer to a surface of the oxide layer, and forming a nitrogen-accumulating layer on an interface defined between the semiconductor substrate and the oxide layer.

The oxide layer is preferably formed through a radical oxidation process. The radical oxidation process is preferably performed under an atmosphere of oxygen (O₂) gas, hydrogen (H₂) gas, and argon (Ar) gas and a temperature of 800° C. to 950° C.

The nitrogen-containing insulating layer preferably comprises a silicon oxynitride (SiON) layer. The nitrogen-containing insulating layer is preferably formed through a plasma nitridation treatment process. The nitrogen-containing insulating layer preferably has a nitrogen concentration of 5 at % to 30 at % after the nitrogen-accumulating layer is formed.

The plasma nitridation treatment process is preferably performed under an atmosphere of hydrogen (H₂) gas and argon (Ar) gas, a pressure of 3 Pa to 10 Pa, power of 150 W to 200 W, and a temperature of 800° C. to 900° C.

The nitrogen-accumulating layer is preferably formed through an annealing process, highly preferably utilizing dinitrogen monoxide (N₂O) gas. The annealing process is preferably performed a pre-activation chamber (PAC) at normal (i.e., atmospheric) pressure and a temperature of 900° C. to 1,100° C. The annealing process is preferably performed in an ex-situ manner after the plasma nitridation treatment process.

### BRIEF DESCRIPTION OF THE DRAWINGS

The foregoing and other features and advantages of the invention will become readily apparent by reference to the following detailed description when considered in conjunction with the accompanying drawings wherein:

FIG. 1A to FIG. 1C are sectional views for illustrating a method of forming a tunnel insulating layer in a flash memory device according to one embodiment of the invention; and

FIG. 2 is a SIMS (secondary ion mass spectroscopy) graph showing a change of concentration of nitrogen according to a change of a depth of the tunnel insulating layer of one embodiment of the invention.

### DESCRIPTION OF SPECIFIC EMBODIMENTS

Preferred embodiments of the invention are explained in more detail with reference to the accompanying drawings.

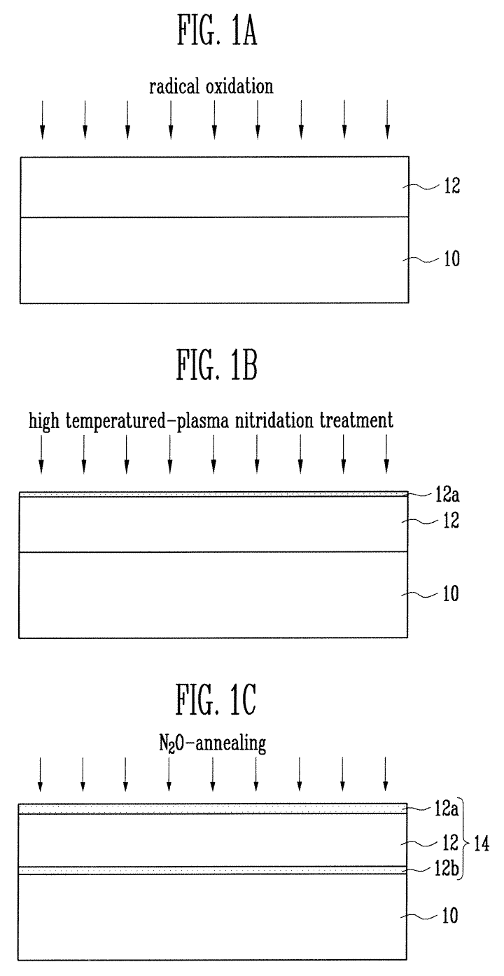

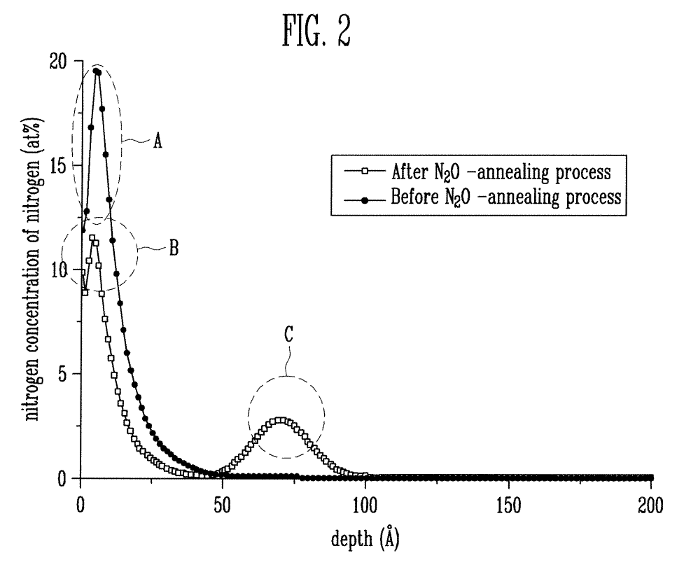

FIG. 1A to FIG. 1C are sectional views for illustrating a method of forming a tunnel insulating layer in a flash memory device according to one embodiment of the invention, and FIG. 2 is a SIMS (secondary ion mass spectroscopy) graph showing a change of concentration of nitrogen according to a change of a depth of the tunnel insulating layer of one embodiment of the invention.

Referring to FIG. 1A, a semiconductor substrate 10 on which a well region (not shown) is formed is provided. The well region is preferably formed with a triple structure. In order to form the well region having the triple structure, a screen oxide layer (not shown) is formed on the semiconductor substrate 10, and a well ion implanting process and a threshold voltage ion implantation process are then performed.

After the screen oxide layer is removed, a cleaning process is preferably further performed prior to forming an oxide layer on the semiconductor substrate 10 (having the well region formed thereon) for forming a tunnel insulating layer. The cleaning process is preferably carried out by using HF solution and standard cleaning-1 (SC-1) solution for removing a natural oxide layer and impurities.

Subsequently, after the screen oxide layer is removed, an oxide layer 12 is formed on the semiconductor substrate 10 on which the well region is formed. The oxide layer is preferably formed through a radical oxidation process. In this case, the radical oxidation process is highly preferably performed under an atmosphere of O₂ gas, H₂ gas, and argon (Ar) gas and a temperature of 800° C. to 950° C. As a result, a pure silicon oxide (SiO₂) layer is formed as the oxide layer 12. The oxide layer 12 preferably has a thickness of 60 Å to 80 Å.

In a case where the oxide layer 12 is formed through the radical oxidation process as described, it is possible to obtain a denser layer to prevent a quality of the tunnel insulating layer from being deteriorated in a subsequent process performed at a high-temperature.

Referring to FIG. 1B, a surface of the oxide layer 12 is nitridized. A nitridation treatment process, illustratively a plasma nitridation treatment, is performed. In this case, in order to more actively perform a chemical reaction as compared with the conventional nitridation treatment process, it is preferred that the plasma nitridation treatment process is performed at a high temperature of 800° C. to 900° C. In addition, the plasma nitridation treatment process is preferably carried out in a gas atmosphere of argon (Ar) gas and nitrogen (N₂) gas, a pressure of 3 Pa to 10 Pa, and a power of 150 W to 200 W.

Oxygen in the silicon-oxygen (Si—O) combination on a surface of the oxide layer 12 is substituted with nitrogen by the plasma nitridation treatment process as described above, so a nitrogen-containing insulating layer 12a is formed on a surface of the oxide layer 12. As a result, one nitrogen peak is formed on the surface of the oxide layer 12.

A nitride layer, preferably at least one of a silicon nitride (Si₃N₄) layer and a silicon oxynitride (SiON) layer is preferably formed as the above nitrogen-containing insulating layer 12a. In a preferred embodiment of the invention, a silicon oxynitride (SiON) layer having a high nitrogen content is mainly formed through a plasma nitridation treatment process. As a result, the silicon oxynitride (SiON) layer can prevent boron from penetrating into a tunnel insulating layer to be formed later to improve a breakdown voltage characteristic or a leakage current characteristic of the tunnel insulating layer.

As compared with a conventional plasma nitridation treatment process performed at a low temperature of 500° C. or less, a chemical reaction is more easily generated in the plasma nitridation treatment process performed at a high temperature of 800° C. or more. Accordingly, as compared with the plasma nitridation treatment process performed at a low temperature, the plasma nitridation treatment process performed at a high temperature can remarkably reduce the trap site. As a result, it is possible to greatly improve a breakdown voltage characteristic or a leakage current characteristic of a tunnel insulating layer to be formed later.

In the meantime, since a surface of the oxide layer 12 is reacted during the nitridation treatment process to form the nitrogen-containing insulating layer 12a, the thickness of the oxide layer 12 is reduced as compared with the thickness of the oxide layer formed in an early phase.

Referring to FIG. 1C, a process for accumulating nitrogen on an interface defined between the semiconductor substrate 10 and the oxide layer 12 is performed. Preferably at this time, an annealing process, highly preferably utilizing dinitrogen monoxide (N₂O) is performed as the process for accumulating nitrogen, and the process for accumulating nitrogen is preferably performed in an ex-situ manner after the nitrogen-containing insulating layer 12a is formed. In this case, the N₂O annealing process is preferably carried out under an atmosphere of dinitrogen monoxide gas, normal (i.e., atmospheric) pressure, and a temperature of 900° C. to 1,100° C. Also, the N₂O annealing process is preferably performed in a pre-activation chamber (PAC) to facilitate decomposition of dinitrogen monoxide (N₂O) gas.

As a result, a nitrogen-accumulating layer 12b to which nitrogen is implanted is formed on an interface between the semiconductor substrate 10 and the oxide layer 12. By virtue of the nitrogen-accumulating layer, another single nitrogen peak is formed on the interface between the semiconductor substrate 10 and the oxide layer 12. Due to the above-described nitrogen-accumulating layer 12b, a density of the interface trap charge, which is inevitably generated on the interface between the semiconductor substrate 10 and the oxide layer 12, can be reduced, and the characteristics of the stress induced leakage current (SILC) and the current-voltage (C-V) can be improved to enhance cycling characteristics and retention characteristics of the tunnel insulating layer to be formed later.

In particular, in one embodiment of the invention, after the N₂O annealing process, the concentration of nitrogen contained in the nitrogen-containing insulating layer 12a is adjusted to 5 at % to 30 at % so that a breakdown voltage characteristic of the tunnel insulating layer to be formed later is improved and a leakage current in the tunnel insulating layer is reduced to improve a leakage current characteristic.

In general, when the N₂O annealing process is performed after the plasma nitridation treatment process, the concentration of nitrogen contained in the nitrogen-containing insulating layer 12a formed on a surface of the oxide layer 12 is reduced by 40% to 50%. Accordingly, in order to obtain nitrogen having a desired concentration and contained in the nitrogen-containing insulating layer 12a after the N₂O annealing process, the conditions of the N₂O annealing process should be tuned and a concentration of nitrogen utilized in the plasma nitridation treatment process should be simultaneously adjusted.

As compared the oxide layer after the nitrogen-containing insulating layer 12a is formed, in the meantime, the thickness of the oxide layer 12 is preferably increased by about 10 Å to 20 Å by the N₂O annealing process. However, the process conditions of the N₂O annealing process preferably should be properly controlled to limit the increment of thickness of the oxide layer 12 after the N₂O annealing process to 1 Å or less. In addition, the thickness of the nitrogen-containing insulating layer 12b can be partially increased by the N₂O annealing process.

Typically, due to the damage of a surface of the oxide layer 12 and the instability of nitrogen which is combined, it is difficult to make use of the advantage of the nitrogen peak so that a subsequent oxygen (O₂) annealing process is performed after the nitridation treatment process. In the illustrated embodiment of the invention, however, since the N₂O annealing process is performed after the nitridation treatment process, the oxygen (O₂) annealing process is omitted after the nitridation treatment to reduce the number of processes and a loss of nitrogen and a densification of the nitrogen-containing insulating layer 12a are promoted to prevent a threshold voltage shift characteristic and a variation characteristic of the tunnel insulating layer to be formed later from being degraded.

Finally, by the plasma nitridation treatment process (carried out at a high temperature) and the N₂O annealing process sequentially performed after the oxide layer 12 is formed, a tunnel insulating layer 14, which is a stack layer consisting of the nitrogen-accumulating layer 12b, the oxide layer 12, and the nitrogen-containing insulating layer 12a is formed.

According to the embodiment of the invention described above, the trap site is remarkably reduced and the tunnel insulating layer 14 including the nitrogen-containing insulating layer 12a illustratively comprising or consisting of the silicon oxynitride (SiON) layer having a high nitrogen content is formed through the plasma nitridation treatment process performed at a high temperature of 800° C. or more, and so it is possible to inhibit boron from penetrating into the tunnel insulating layer 14 to improve the leakage current characteristic and the breakdown voltage characteristic of the tunnel insulating layer.

In general, a nitride layer such as a silicon nitride (Si₃N₄) layer and a silicon oxynitride (SiON) layer has a dielectric ratio of about 7, while the silicon oxide (SiO₂) layer has the dielectric ratio of about 3.9. Accordingly, in a case where the tunnel insulating layer 14 includes the nitrogen-containing insulating layer 12a comprising or consisting of the silicon oxynitride (SiON) layer, the physical thickness of the tunnel insulating layer 14 can be increased by reducing the equivalent oxide thickness (EOT) of the tunnel insulating layer 14 to improve the cycling and retention characteristics.

Referring to FIG. 2, prior to performing the N₂O annealing process, the tunnel insulating layer 14 according to one embodiment of the invention as shown in FIGS. 1A, 1B, and 1C has one nitrogen peak (indicated by “A” in FIG. 2) formed on a surface thereof by the nitrogen-containing insulating layer 12a obtained during the plasma nitridation treatment process. After the N₂O annealing process is completed, the tunnel insulating layer 14 has the double nitrogen peaks consisting of one nitrogen peak (indicated by “B” in FIG. 2) formed on a surface thereof by the nitrogen-containing insulating layer 12a and having a nitrogen concentration smaller than that of the nitrogen peak “A” and the other nitrogen peak (indicated by “C” in FIG. 2) formed on an interface between the semiconductor substrate 10 and the tunnel insulating layer 14 by the nitrogen-accumulating layer 12b obtained during the N₂O annealing process. At this time, it can be verified that a nitrogen concentration of the nitrogen peak B on a surface of the final tunnel insulating layer 14 is maintained at 7 at % or more.

Accordingly, although the tunnel insulating layer 14 according to one embodiment of the invention has dual nitrogen peaks, the nitrogen concentration of a surface of the tunnel insulating layer 14 is illustratively maintained at 5 at % or more, the tunnel insulating layer includes the nitrogen-containing insulating layer 12a formed of the silicon oxynitride (SiON) layer with a high nitrogen content and is densified by the above the nitrogen-containing insulating layer. Accordingly, the invention can improve the breakdown voltage characteristic, the leakage current characteristic, the cycling characteristic, the retention characteristic, the threshold voltage shift characteristic, and the variation characteristic to improve the reliability of the device.

Although not shown in the drawings, after the tunnel insulating layer 14 is formed, a polysilicon layer is preferably formed for forming a floating gate and a subsequent process is then performed to complete a process for manufacturing the semiconductor device.

The invention has the following effects.

First, a trap site can be remarkably reduced by forming a tunnel insulating layer through a nitridation treatment process, preferably a plasma nitridation treatment process, highly preferably performed at a high temperature of 800° C. or more, and penetration of boron is inhibited by forming a silicon oxynitride (SiON) layer, and so the breakdown voltage characteristic and the leakage current characteristic are improved.

Second, the equivalent oxide thickness (EOT) of the tunnel insulating layer is reduced by applying a plasma nitridation treatment process, and the physical thickness of the tunnel insulation layer can be increased due to reduction of the EOT. Consequently, the cycling and retention characteristics can be improved.

Thirdly, instead of a subsequent O₂ annealing process performed when a conventional plasma nitridation treatment process is applied, the N₂O annealing process utilized for forming the tunnel insulating layer is performed after a plasma nitridation treatment process. Accordingly, the number of processes is reduced, and a loss of nitrogen and a densification of the nitrogen-containing insulating layer on a surface of the oxide layer are promoted to prevent the threshold voltage shift characteristic and the variation characteristic from being degraded.

Although embodiments have been described with reference to a number of illustrative embodiments thereof, numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses may also be apparent to those skilled in the art.

What is claimed is:

1. A method of forming a tunnel insulating layer in a flash memory device, comprising:
forming an oxide layer on a semiconductor substrate;
forming a nitrogen-containing layer to a surface of the oxide layer; and
forming a nitrogen-accumulating layer on an interface defined between the semiconductor substrate and the oxide layer.

2. The method of claim 1, comprising forming the oxide layer through a radical oxidation process.

3. The method of claim 2, comprising performing the radical oxidation process at a temperature of 800° C. to 950° C.

4. The method of claim 2, comprising performing the radical oxidation process under an atmosphere of oxygen (O₂) gas, hydrogen (H₂) gas, and argon (Ar)gas.

5. The method of claim 1, comprising forming the nitrogen-containing insulating layer through a plasma nitridation treatment process.

6. The method of claim 5, comprising performing the plasma nitridation treatment process under an atmosphere of hydrogen (H₂) gas and argon (Ar) gas.

7. The method of claim 5, comprising performing the plasma nitridation treatment process at a temperature of 800° C. to 900° C.

8. The method of claim 5, comprising performing the plasma nitridation treatment process at a pressure of 3 Pa to 10 Pa and a power of 150 W to 200 W.

9. The method of claim 1, wherein the nitrogen-containing insulating layer comprises a silicon oxynitride (SiON) layer.

10. The method of claim 1, comprising forming the nitrogen-accumulating layer through an annealing process utilizing dinitrogen monoxide (N₂O) gas.

11. The method of claim 10, comprising performing the annealing process under atmospheric pressure and a temperature of 900° C. to 1,100° C.

12. The method of claim 10, comprising performing the annealing process in a pre activation chamber (PAC).

13. The method of claim 10, comprising performing the annealing process in an ex-situ manner after forming the nitrogen-containing insulating layer.

14. The method of claim 1, wherein the nitrogen-containing insulating layer has a nitrogen concentration of 5 at % to 30 at % after the nitrogen-accumulating layer is formed.
